(19) United States
(12) Patent Application Publication
(10) Pub. No.: US 2026/0206160 A1
(43) Pub. Date: Jul. 16, 2026

(54) HOLDER FOR MAGNETIC SUBSTANCE

(71) Applicant: LG INNOTEK CO., LTD., Seoul (KR)

(72) Inventor: Ji Hwan JEON, Seoul (KR)

(73) Assignee: LG INNOTEK CO., LTD., Seoul (KR)

(21) Appl. No.: 19/136,168

(22) PCT Filed: Dec. 6, 2023
(86) PCT No.: PCT/KR2023/020040

§ 371 Date: Jun. 5, 2025

(30) Foreign Application Priority Data
Dec. 6, 2022 (KR) 10-2022-0168492

(51) Int. Cl. H05K 7/14

(52) U.S. Cl. CPC H05K 7/14

(57) ABSTRACT

A holder for a magnetic substance, according to one embodiment of the present invention, comprises: a frame having a through hole formed therein and a first fastening part formed on the outer surface thereof; a magnetic substance disposed on the outer surface of the frame and having a through hole formed therein; and a fixing part disposed on the outer surface of the frame and having a through hole formed therein, wherein a second fastening part corresponding to the first fastening part is formed on an inner surface of the through hole of the fixing part.

### TECHNICAL FIELD

The present invention relates to a magnetic substance holder, and more specifically, to a magnetic substance holder having a fixed type holder structure capable of fixing a magnetic substance to a housing, and an electronic device including the same.

### BACKGROUND ART

Ferrite core beads remove noise below a certain frequency from the electromagnetic waves emitted by electronic devices. Metal that matches the capacity of the cable is used by penetrating the cable, while existing beads are connected by extruding the case and fastening the produced case between the cables.

When attaching a ferrite core bead to a cable, it is usually secured only to the cable with a cable tie and a shrink tube, and is not secured inside an electronic device such as an inverter. Since there is a metal weight contained in the core, an unsecured ferrite core bead may move inside the electronic device, which may cause damage to major components or the case.

### DETAILED DESCRIPTION OF THE INVENTION

### Technical Subject

The technical problem to be solved by the present invention is to provide a magnetic substance holder having a fixed type holder structure capable of fixing a magnetic substance to a housing, and an electronic device including the same.

### Technical Solution

In order to solve the above technical problem, a magnetic substance holder according to one embodiment of the present invention comprises: a frame having a through hole formed therein and a first fastening part formed on an outer surface thereof; a magnetic substance being disposed on an outer surface of the frame and having a through hole formed therein; and a fixing part being disposed on an outer surface of the frame and having a through hole being formed therein, wherein a second fastening part corresponding to the first fastening part is formed on the inner surface of the through hole of the fixing part.

In addition, the first fastening part may include a plurality of first hook-coupling parts having different separation distances from one end of the frame.

In addition, the position of the first fastening part may correspond to the length of the magnetic substance in a lengthwise direction.

In addition, the first fastening part includes a plurality of first fastening parts, and includes at least one planar surface along a lengthwise direction among an outer surface of the frame, wherein at least one first fastening part can be disposed on the planar surface.

In addition, the first fastening part includes a plurality of first fastening parts, wherein an outer surface of the frame has a polygonal shape, and wherein at least one first fastening part can be disposed on one surface among surfaces forming the polygonal shape.

In addition, the first fastening part includes a first screw thread, wherein the second fastening part may include a second screw thread corresponding to the first screw thread.

In addition, a plurality of holes may be formed in a circumferential direction on an outer surface of the frame.

In addition, it includes a gasket being disposed on an outer surface of the frame in which a through hole is formed, wherein the gasket can be disposed between the fixing part and the magnetic substance.

In addition, a cross-sectional area of a through hole of the magnetic substance and a cross-sectional area of a through hole of the fixing part may correspond to a cross-sectional area of the frame.

In addition, it may include a third fastening part being coupled with a housing to which the magnetic substance holder is fixed at one end of the frame.

In addition, the third fastening part may comprise: at least one guide part being protruded in a circumferential direction from an outer surface of the frame; at least one second hook-coupling part being formed on an outer surface of the frame and spaced apart from the guide part; and an engagement part being protruded in a circumferential direction along a perimeter of an outer surface of the frame.

In order to solve the above technical problem, according to an embodiment of the present invention, an electronic device comprises: a first housing and a second housing having a coupling part being protruded from surfaces facing each other and being formed with a through hole in the coupling part; and at least one magnetic substance holder being disposed on a through passage formed when the first housing and the second housing are coupled, wherein a support part is formed to support the magnetic substance holder across a through hole of at least one of the first housing and the first housing, and wherein the magnetic substance holder includes at least a portion of configuration of the magnetic substance holder described above.

### Advantageous Effects

According to embodiments of the present invention, the magnetic substance can be mounted on a cable, but can be directly fixed to a case to ensure stability and handling reliability. In addition, the magnetic substance can be disposed in a through-hole between cases to increase space utilization, and easy assembly is possible, so that it can be inserted in the middle of the cable and the fixing man-hours can be saved. Furthermore, it is highly compatible by being adaptively fixed according to the size of the magnetic substance.

### BRIEF DESCRIPTION OF DRAWINGS

FIG. 1 is a perspective view of a magnetic substance holder according to an embodiment of the present invention.

FIG. 2 is an exploded perspective view of a magnetic substance holder according to an embodiment of the present invention.

FIG. 3 is a cross-sectional view of a magnetic substance holder according to an embodiment of the present invention.

FIG. 4 is a perspective view of a magnetic substance holder excluding a magnetic substance according to an embodiment of the present invention.

FIG. 5 is an exploded perspective view of a magnetic substance holder excluding a magnetic substance according to an embodiment of the present invention.

FIG. 6 is a perspective view of a frame according to an embodiment of the present invention.

FIG. 7 is a cross-sectional view of a frame according to an embodiment of the present invention.

FIG. 8 is a perspective view of a fixing part according to an embodiment of the present invention.

FIG. 9 is a perspective view of a gasket according to an embodiment of the present invention.

FIG. 10 is a perspective view of a magnetic substance according to an embodiment of the present invention.

FIG. 11 is a perspective view of a magnetic substance holder according to another embodiment of the present invention.

FIG. 12 is an exploded perspective view of a magnetic substance holder according to another embodiment of the present invention.

FIG. 13 is a perspective view of a frame according to another embodiment of the present invention.

FIG. 14 is a perspective view of a fixing part according to another embodiment of the present invention.

FIG. 15 illustrates a magnetic substance holder assembly form according to a length of the magnetic substance.

FIG. 16 illustrates a housing of an electronic device including a magnetic substance holder positioned in a housing coupling through passage.

FIGS. 17 to 19 illustrate a magnetic substance holder coupled with a housing.

FIG. 20 illustrates a frame coupled with a housing.

FIG. 21 illustrates a magnetic substance holder coupled with a housing.

FIG. 22 illustrates a magnetic substance holder coupled to a housing according to different types of embodiments.

### BEST MODE

Hereinafter, preferred embodiments of the present invention will be described in detail with reference to the accompanying drawings.

However, the technical idea of the present invention is not limited to some embodiments to be described, but may be implemented in various forms, and within the scope of the technical idea of the present invention, one or more of the constituent elements may be selectively combined or substituted between embodiments.

In addition, the terms (including technical and scientific terms) used in the embodiments of the present invention, unless explicitly defined and described, can be interpreted as a meaning that can be generally understood by a person skilled in the art, and commonly used terms such as terms defined in the dictionary may be interpreted in consideration of the meaning of the context of the related technology.

In addition, terms used in the present specification are for describing embodiments and are not intended to limit the present invention. In the present specification, the singular form may include the plural form unless specifically stated in the phrase, and when described as “at least one (or more than one) of A and B and C”, it may include one or more of all combinations that can be combined with A, B, and C.

In addition, in describing the components of the embodiment of the present invention, terms such as first, second, A, B, (a), and (b) may be used.

These terms are merely intended to distinguish the components from other components, and the terms do not limit the nature, order or sequence of the components.

And, when a component is described as being ‘connected’, ‘coupled’ or ‘interconnected’ to another component, the component is not only directly connected, coupled or interconnected to the other component, but may also include cases of being ‘connected’, ‘coupled’, or ‘interconnected’ due that another component between that other components.

In addition, when described as being formed or disposed in “on (above)” or “below (under)” of each component, “on (above)” or “below (under)” means that it includes not only the case where the two components are directly in contact with, but also the case where one or more other components are formed or disposed between the two components. In addition, when expressed as “on (above)” or “below (under)”, the meaning of not only an upward direction but also a downward direction with respect to one component may be included.

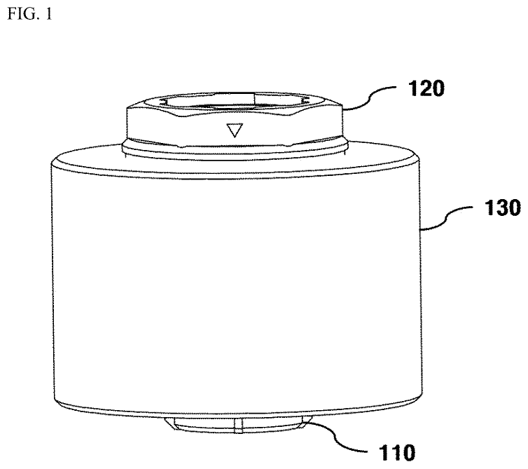

FIG. 1 is a perspective view of a magnetic substance holder according to an embodiment of the present invention.

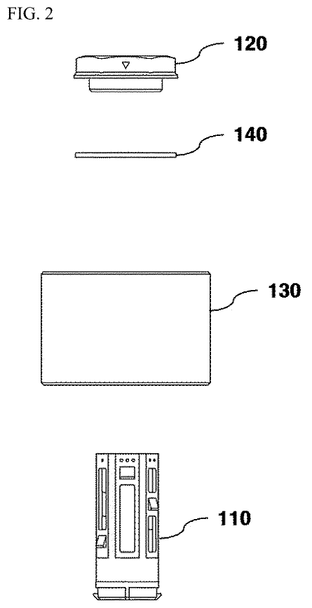

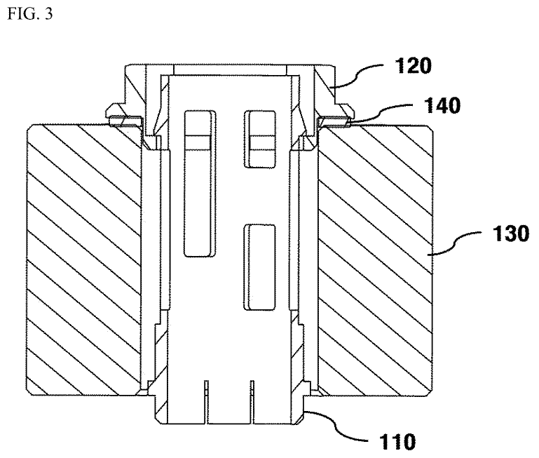

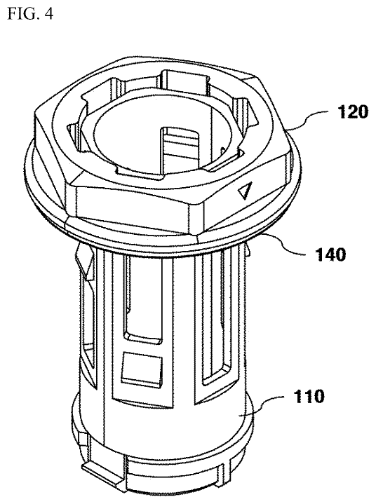

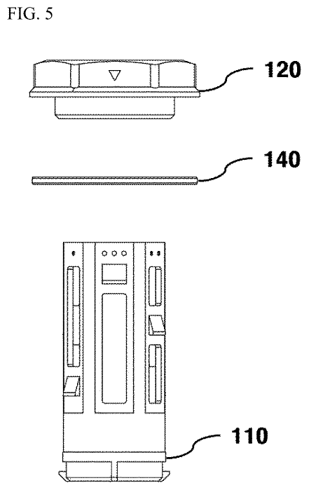

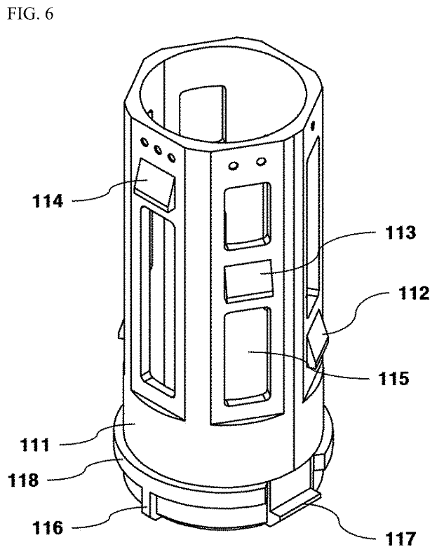

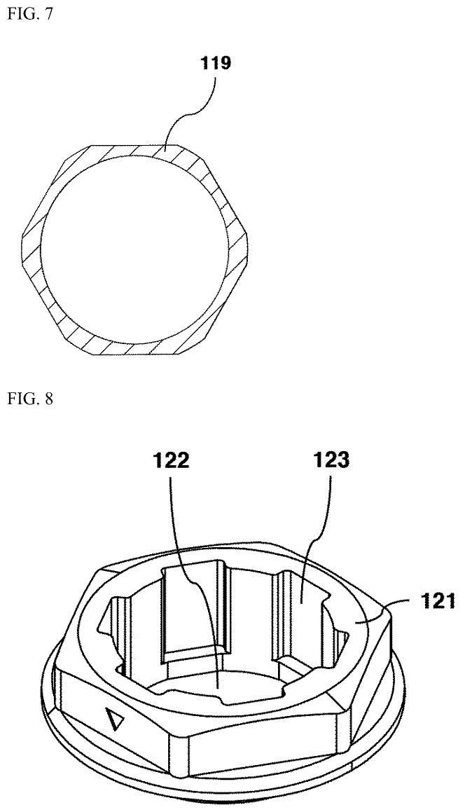

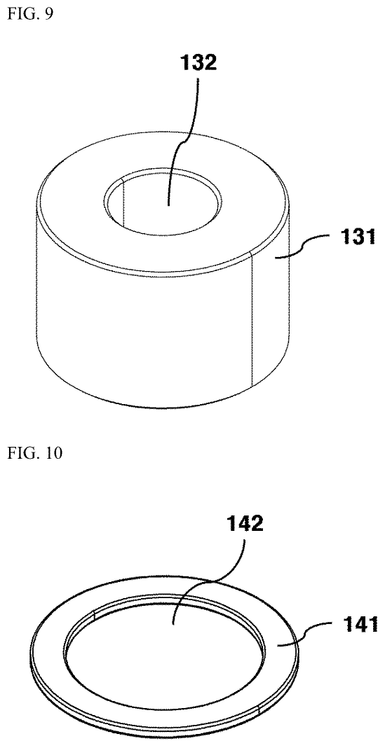

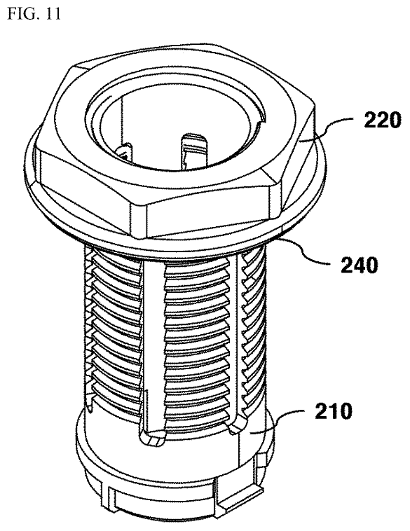

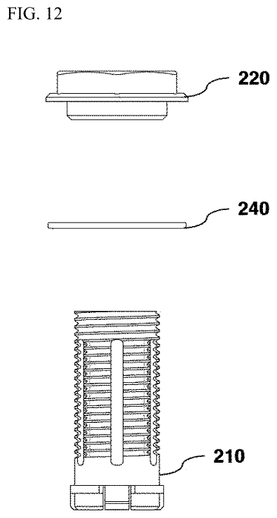

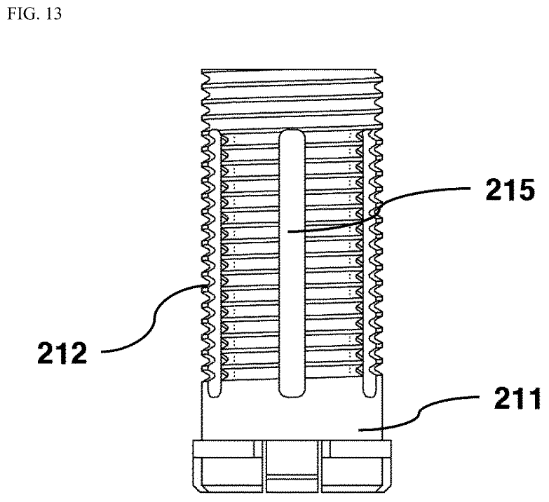

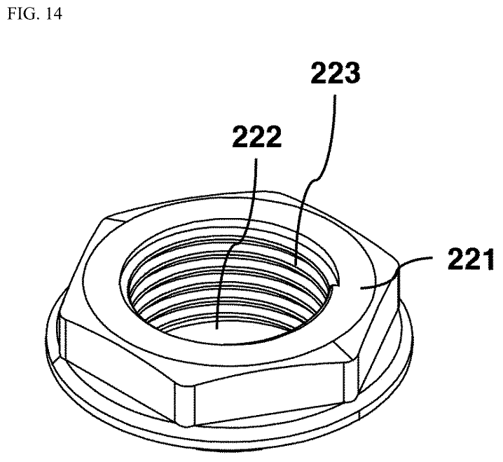

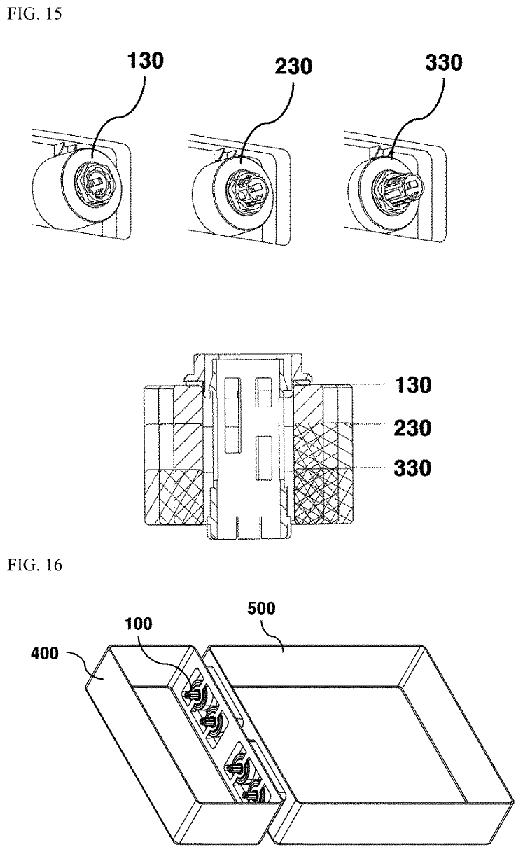

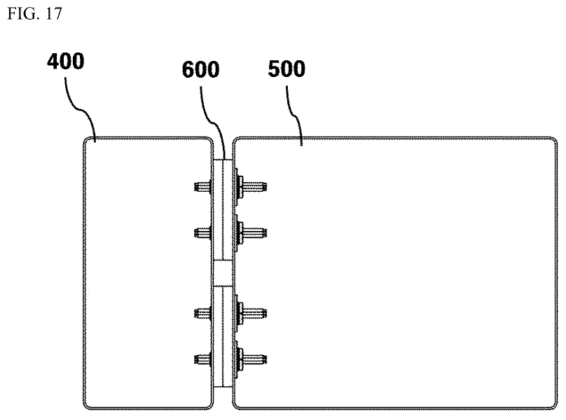

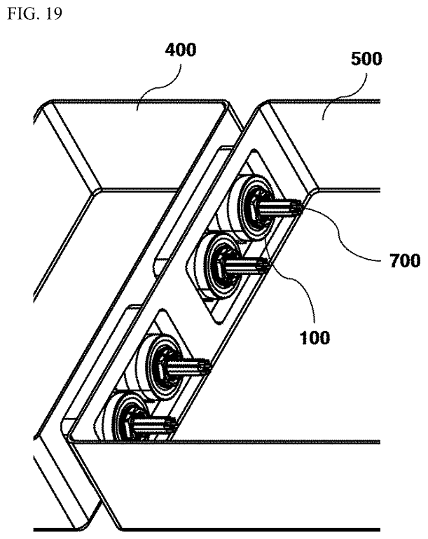

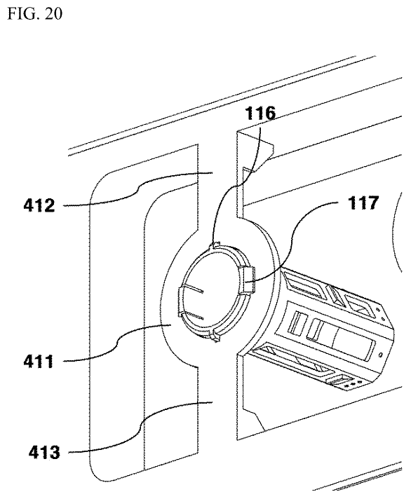

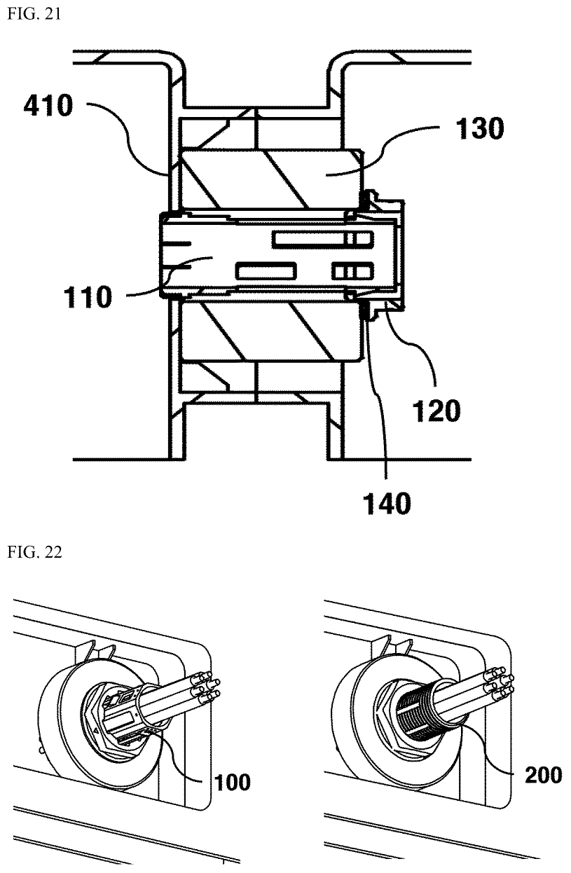

FIG. 2 is an exploded perspective view of a magnetic substance holder according to an embodiment of the present invention; FIG. 3 is a cross-sectional view of a magnetic substance holder according to an embodiment of the present invention; FIG. 4 is a perspective view of a magnetic substance holder excluding a magnetic substance according to an embodiment of the present invention; FIG. 5 is an exploded perspective view of a magnetic substance holder excluding a magnetic substance according to an embodiment of the present invention; FIG. 6 is a perspective view of a frame according to an embodiment of the present invention; FIG. 7 is a cross-sectional view of a frame according to an embodiment of the present invention; FIG. 8 is a perspective view of a fixing part according to an embodiment of the present invention; FIG. 9 is a perspective view of a gasket according to an embodiment of the present invention; FIG. 10 is a perspective view of a magnetic substance according to an embodiment of the present invention; FIG. 11 is a perspective view of a magnetic substance holder according to another embodiment of the present invention; FIG. 12 is an exploded perspective view of a magnetic substance holder according to another embodiment of the present invention; FIG. 13 is a perspective view of a frame according to another embodiment of the present invention; FIG. 14 is a perspective view of a fixing part according to another embodiment of the present invention; FIG. 15 illustrates a magnetic substance holder assembly form according to a length of the magnetic substance; FIG. 16 illustrates a housing of an electronic device including a magnetic substance holder positioned in a housing coupling through passage; FIGS. 17 to 19 illustrate a magnetic substance holder coupled with a housing; FIG. 20 illustrates a frame coupled with a housing; FIG. 21 illustrates a magnetic substance holder coupled with a housing; and FIG. 22 illustrates a magnetic substance holder coupled to a housing according to different types of embodiments.

A magnetic substance holder 100 according to one embodiment of the present invention is configured with a frame 110, a magnetic substance 130, a fixing part 120, and may include a gasket 140.

A through hole is formed inside the frame 110, a fixing part 120 is disposed on an outer surface of the frame 110, and a through hole is formed. A magnetic substance 130 is disposed on an outer surface of the frame, a through hole is formed, and a fixing part 120 is disposed on an outer surface of the frame 110, and a through hole is formed.

A through hole is formed inside the frame 110 so that a cable can penetrate through it. The through hole is formed in a lengthwise direction from one end of the frame 110 to the other end. The through hole being formed inside the frame 110 can be referred to as a cable through hole. The through hole being formed inside the frame 110 can be formed in a circular or polygonal shape, and can be formed in various shapes. The through hole can be formed with an area larger than the cross-sectional area of the cable so that cables of various diameters can penetrate through it.

A through hole is formed in the fixing part 120 or the magnetic substance 130 so that the frame 110 can penetrate therethrough. The magnetic substance 130 may be formed as a body part 131 in which a through hole 132 is formed, and the fixing part 120 may be formed as a body part 121 in which a through hole 122 is formed. The cross-sectional area of a through hole of the magnetic substance 130 or the cross-sectional area of a through hole of the fixing part 120 may correspond to the cross-sectional area of the frame 110. The cross-sectional area of a through hole of the magnetic substance 130 or the cross-sectional area of a through hole of the fixing part 120 may be equal to or larger than the cross-sectional area of the frame 110. The shape of an inner surface of a through hole of the magnetic substance 130 or the shape of an inner surface of a through hole of the fixing part 120 corresponds to the shape of an outer surface of the frame 110, so that the magnetic substance 130 or the fixing part 120 can be inserted into the through hole of the outer surface of the frame 110 and combined.

A magnetic substance (magnetic material) is a material that can have magnetic force, and can include a material that has magnetism or has magnetism when located within the magnetic force of a material having magnetism. A magnetic substance can include a ferromagnetic substance, a paramagnetic substance, and a diamagnetic substance. The magnetic substance can include ferrite. Ferrite is hard and brittle and is formed as a polycrystal containing iron, and includes iron oxide and one or more other metals. Ferrite can be formed by a reaction between iron oxide and various other metals such as magnesium, aluminum, barium, manganese, copper, nickel, cobalt, and iron. The magnetic substance 120 has ferromagnetism and is installed by penetrating a cable 150 to remove noise below a certain frequency from electromagnetic waves. It can be composed of various materials used as a magnetic substance. The magnetic substance 130 can be formed in the form of a core bead by forming a through hole. It can be expressed as a magnetic substance, a magnetic substance core, a magnetic substance bead, a magnetic substance core bead, and the like.

The fixing part 120 can serve as a retainer. The retainer can serve as a fixing device to fix a magnetic substance. The fixing part 120 can be referred to as a holder cap that covers a magnetic substance holder 100.

When coupled with the frame 110, the magnetic substance 130 and the fixing part 120 can be coupled in that order. The fixing part 120 is coupled after the magnetic substance 130 is coupled, so as to prevent the magnetic substance 130 fitted into the frame 110 from being separated to the outside. To this end, a first fastening part can be formed on an outer surface of the frame 110, and a second fastening part corresponding to the first fastening part can be formed on an inner surface of a through hole of the fixing part 120.

The first fastening part and the second fastening part are formed in a shape corresponding to each other to prevent them from being separated in the opposite direction to a direction in which they are coupled when fastened. The first fastening part and the second fastening part can be coupled by means of a fit-coupling, a hook-coupling, or a screw-coupling or the like.

The first fastening part may include at least one first hook-coupling part, and the second fastening part may include a groove that is hook-coupled with the first hook-coupling part. The first hook-coupling part 112 and the groove 123 may surface-bonded in a direction opposite to the fastening direction when fastened, thereby preventing the fixing part 120 from being separated from the frame 110.

The fixing part 120 may include a body 121 in which a through hole is formed and one or more grooves 123 being formed on an inner surface. The inner surface of the fixing part 120 may have a shape corresponding to an outer surface of the frame 110, and a groove 123 may be formed as a second fastening part corresponding to the first fastening part implemented as the first hook-coupling parts 112 to 114. The groove 123 may have an engagement threshold formed therein to prevent separation after being fastened with the first hook-coupling parts 112 to 114. That is, the hook of the first hook-coupling parts 112 to 114 and the engagement threshold of the groove 123 may be caught to prevent the fixing part 120 from being separated from the frame 110.

When the frame 110 and the fixing part 120 are fastened through the first fastening part and the second fastening part, the magnetic substance 130 located inside the fixing part 120 is also fixed to prevent it from being separated from the frame 110.

A gasket 140 may be included between the magnetic substance 130 and the fixing part 120. The gasket 140 may be formed as a body part 141 in which a through hole 142 is formed. The gasket 140 has a belt shape and is disposed between the magnetic substance 130 and the fixing part 120, and may be disposed between the surfaces where the magnetic substance 130 and the fixing part 120 come into contact so that the magnetic substance 130 and the fixing part 120 can be in close contact with each other to maintain a tightening pressure. In order for the magnetic substance 130 to be fixed by the fixing part 120, a separation space must not be formed between the magnetic substance 130 and the fixing part 120, and if there is a separation space, a space is created in which the magnetic substance 130 can move, so that the magnetic substance 130 is not fixed when subjected to an external impact, and thus the coupling may be detached or other parts may be affected. The separation space between the magnetic substance 130 and the fixing part 120 may be formed with a tolerance or for ease of assembly. The gasket 140 is disposed between the magnetic substance 130 and the fixing part 120 to fill the space between the magnetic substance 130 and the fixing part 120. This can prevent problems due to tolerance, and can play a role in assisting the gap when the length of the magnetic substance 130 does not correspond to the position of the fixing part 120.

The gasket 140 may be formed of an elastic material. The gasket 140 may be formed of metal, plastic, rubber, or the like. The gasket 140 may also be referred to as packing. When coupled with the frame 110, the magnetic substance 130, the gasket 140, and the fixing part 120 may be coupled in that order.

The first fastening part may include a plurality of first hook-coupling parts 112 to 114 having different separation distances from one end of the frame 110. The magnetic substance 130 may use different types of magnetic substances having different lengths in a lengthwise direction. The length of the magnetic substance 130 in a lengthwise direction may vary depending on the required magnetic substance capacity depending on the size of the current, voltage, power, and noise of the cable passing through the through hole of the frame 110. Depending on the type of length of the applicable magnetic substance 130, the first hook-coupling parts may be formed at a plurality of positions corresponding to the corresponding length. As shown in FIG. 15, when three types of magnetic substances 130 having different lengths are used, the first hook-coupling parts 112 to 114 having three distances from one end of the frame 110 may be included. When the magnetic substance 130 having the longest length is used, the second fastening part of the fixing part 120 can be fastened to the first hook-coupling part 114 having the farthest distance from one end of the frame 110. When the magnetic substance 230 having an intermediate length is used, the second fastening part of the fixing part 120 can be fastened to the first hook-coupling part 113 having an intermediate distance from one end of the frame 110. When the magnetic substance 330 having the shortest length is used, the second fastening part of the fixing part 120 can be fastened to the first hook-coupling part 112 having the shortest distance from one end of the frame 110. The number of the first hook-coupling parts can also increase or decrease depending on the type of the magnetic substance 130.

The first fastening part includes a plurality of first fastening parts, and includes at least one planar surface 119 along a lengthwise direction of an outer surface of a frame 110, and at least one first fastening part can be disposed on the planar surface 119. An inner surface of the frame 110 is formed in a circular shape, and an outer surface of the frame is also formed in a circular shape, but a position where the first fastening part is disposed can be formed as a surface having a planar shape. An outer surface of the frame 110 has a polygonal shape, and at least one first fastening part can be disposed on one surface among the surfaces forming the polygonal shape.

For example, as shown in FIG. 7, planar surfaces 119 may be formed in six directions from a basic circular shape. At this time, the outer surface of the frame 110 may have a hexagonal shape, but the corner region may have a round shape. Six surfaces are formed in six directions, and a first fastening part having the same separation distance as one end of the frame 110 may be formed on surfaces facing each other to correspond to both surfaces. By forming two first fastening parts in a direction facing each other, it may be more firmly fastened with the second fastening part. The position of the first fastening part formed on one surface may be different from the positions of the first fastening parts being formed on the adjacent two surfaces.

Or, an outer surface of the frame 110 may be formed in a circular shape, but may include one planar surface or two planar surfaces positioned in opposite directions from the center. In the case of including one planar surface, a plurality of first fastening parts having different separation distances from one end of the frame 110 may be formed on a surface of the planar surface. In the case of including two planar surfaces, a plurality of first fastening parts may be formed to correspond to each other. The first fastening part and the second fastening part are fastened so as to be caught in a separation direction, but can move in a coupling direction. That is, the second fastening part may be sequentially fastened and moved from the first hook-coupling part 114 having the farthest separation distance from one end of the frame 110 to the first hook-coupling part 112 having the shortest separation distance from one end of the frame 110 until the fixing part 120 is prevented from moving in the coupling direction by the magnetic substance 130. At the final fastening position, the first fastening part and the second fastening part are fastened so that the frame 110, the magnetic substance 130, and the fixing part 120 can be fixed.

Or, the first fastening part may include one first hook-coupling part 114, and the gap between the magnetic substance 130 and the fixing part 120 may be filled with a gasket 140 to fix the first fastening part. That is, when a gap is created between the magnetic substance 130 and the fixing part 120 due to the fastening of the first fastening part and the second fastening part, the gap may be filled by inserting a gasket that matches the gap to fix the first fastening part.

A plurality of holes 115 may be formed in a circumferential direction on an outer surface of the frame 110. The magnetic substance 130 is for removing noise being generated from a cable penetrating the through hole of the frame 110, and the noise removing effect can be enhanced only when there is no overlapping configuration between the magnetic substance 130 and the cable 700. That is, a plurality of holes 115 may be formed in a circumferential direction connecting an inner surface and an outer surface of the frame 110 so that the magnetic substance 130 and the cable 700 penetrating the inside of the frame 110 can directly face each other without any other configuration. The holes 115 may be formed at a location other than a location where the first fastening part is formed.

One end of the frame 110 may include a third fastening part being coupled with a housing 400 to which a magnetic substance holder 100 is fixed. The frame 110 may include a third fastening part at one end of the frame 110 so as to be fixed to the housing 400. The third fastening part may be coupled to the housing 400 through hook-coupling.

The third fastening part may include at least one guide part 116 protruding circumferentially from the outer surface of the frame 110, at least one second hook-coupling part 117 formed on the outer surface of the frame 110 and spaced apart from the guide part 116, and an engagement threshold part 118 being protruded circumferentially along the perimeter of an outer surface of the frame 110. The frame 110 may be fixed to the coupling part in which a coupling hole of the housing 400 is formed. One end of the frame 110 may be inserted into the coupling hole formed in the housing 400 to be coupled with the housing 400. At this time, the guide part 116 may be formed to be protruded circumferentially from an outer surface of the frame 110 and may be fitted into a groove formed in a portion of the coupling holes of the housing 400 corresponding to the guide part 116 to guide the coupling. The second hook-coupling part 117 can be fitted into a coupling hole being formed in the housing 400 and hook-coupled with one surface of the inner side of the coupling part of the housing 400. In addition, the coupling part 410 of the housing 400 is positioned between the second hook-coupling part 117 and an engagement threshold part 118 that is spaced apart from the second hook-coupling part 117 in a lengthwise direction of the frame 110 and protruded circumferentially along the perimeter of an outer surface of the frame 110, and can be fixed between the engagement threshold part 118 and the second hook-coupling part 117. The engagement threshold part 118 may not be formed at a position where the second hook-coupling part 117 is formed. Since it is difficult for the second hook-coupling part 117 to have elasticity when the engagement threshold part 118 is formed at the corresponding position, the second hook-coupling part 117 can be made to have elasticity.

The first fastening part and the second fastening part may be connected by screw-coupling rather than hook-coupling. As shown in FIG. 11, screw threads may be formed on an outer surface of the frame 110 and an inner surface of the fixing part 120 so that the fixing part 120 may be connected by screw-coupling when connected to the frame 110. That is, the first fastening part of the frame 110 may include a first screw thread 212, and the second fastening part of the fixing part 120 may include a second screw thread 223 corresponding to the first screw thread 212. The frame 110 includes the first screw thread 212 being formed on an outer surface of the body portion 211.

A plurality of holes 215 may be formed in a circumferential direction on an outer surface of the frame 110. The magnetic substance 130 is for removing noise being generated from a cable penetrating the through hole of the frame 110, and the noise removing effect can be enhanced only when there is no overlapping configuration between the magnetic substance 130 and the cable 700. That is, a plurality of holes 215 may be formed in a circumferential direction connecting an inner surface and an outer surface of the frame 110 so that the magnetic substance 130 and the cable 700 penetrating the inside of the frame 110 can directly face each other without any other configuration. A plurality of holes 215 may be formed along a lengthwise direction of the frame 110 at a location where the first screw thread 212 is formed.

A second screw thread 223 is formed on an inner surface of a through hole 222 being formed in the body part 221 of the fixing part 120 and can be screw-coupled with the first screw thread 212. At this time, an outer surface of the body part 221 of the fixing part 120 is formed in a hexagonal shape, so that when the fixing part 120 and the frame 110 are screw-connected, assembly can be easily performed using a hexagonal wrench, and the like.

The fixing part 120 and the frame 110 are screw-coupled, and the separation distance from one end of the frame 110 to the fixing part 120 can be adjusted through the degree of screw-coupling. In other words, even if the length of the magnetic substance 130 in a lengthwise direction varies, fixing is possible. In the case of using a hook-coupling, the length of the applicable magnetic substance 130 may be limited depending on the position of the hook, but in the case of screw-coupling, magnetic substances 130 of various lengths can be used. In other words, the compatibility with types of magnetic substances having various lengths is increased. In addition, while it is difficult to control the coupling strength when hook-coupling, it is possible to control the coupling strength when screw-coupling, so that problems such as breakage that may occur during work can be prevented.

An electronic device according to an embodiment of the present invention includes a first housing 400, a second housing 500, and a magnetic substance holder 100, and may include a cable 700 penetrating the first housing 400 and the second housing 500 or a driving unit (not shown) for driving the electronic device. A detailed description of the magnetic substance holder corresponds to the detailed description of the magnetic substance holder of FIGS. 1 to 15, and thus, any overlapping description will be omitted below.

An electronic device including a magnetic substance holder is a device in which two housings are connected, a cable for transmitting and receiving power or signals is connected between the housings, and a magnetic substance is applied to the cable, and may be, for example, a PV inverter module. The PV inverter module is a device that receives power from a PV panel or a PV converter and converts it into power that can be used in a home or a building, and receives DC power such as a PV converter, converts it into AC power, and outputs it. At this time, the DC power is transmitted to an inverter driving unit located inside the housing through a wiring box, and the inverter driving unit converts the power, and then transmits the converted power to a load again through the wiring box. The inverter driving unit may include a power conversion element and a switching element or an MCU for controlling the power conversion element. The power conversion element may include a passive element such as an inductor or a capacitor, and may include a switching element implemented as an FET or a diode, and may include an MCU for controlling the switching element. In addition, various elements for converting power may be included, or elements for implementing functions other than power conversion may be included. PV inverter modules have large fluctuations voltage and current being inputted or outputted depending on the amount of solar power generation, and the like, so noise may occur in the input/output cables, so it is necessary to apply a magnetic substance. In addition, it can be applied to various electronic devices.

The first housing 400 and the second housing 500 have coupling parts being protruded from facing surfaces and through holes formed in the coupling parts. A protruded portion may be formed along an outer periphery of the coupling part at an end of one of the first coupling part and the second coupling part being in contact with each other, and a groove corresponding to the protruded portion may be formed along an outer periphery of the coupling part at an end of the other coupling part, and the protruded portion may be fitted into the groove and coupled. A sealing member is positioned between the protruded portion and the groove, so as to perform waterproofing and dustproofing when coupled. The first housing 400 and the second housing 500 may be coupled through screw-coupling while the protruded portion is fitted into the groove. At this time, the through holes being formed in the coupling parts are connected to each other, so that the internal spaces of the first housing 400 and the second housing 500 are connected to each other through the through holes.

Here, the first housing 400 and the second housing 500 transmit and receive power or signals through a cable 700, and the cable 700 is connected through a through hole being formed in the coupling part. Here, the coupling part 600 may include one or two through holes, and an input cable may penetrates through one of the two through holes, and an output cable may penetrate through the other one.

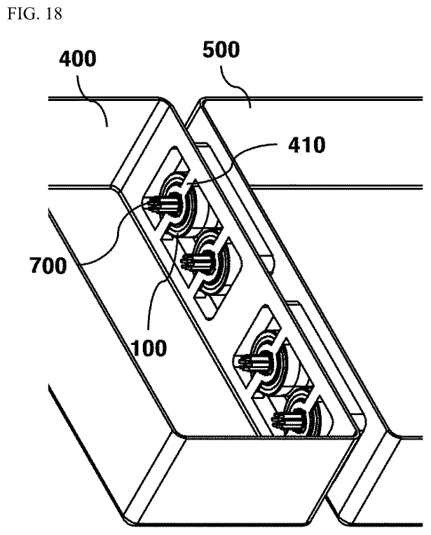

The magnetic substance holder 100 may be disposed on a penetrating through passage being formed when the first housing 400 and the second housing 500 are coupled. At least one of the first housing 400 and the second housing 500 may be formed with at least one support part 410 that supports the magnetic substance holder 100 across a through hole of the corresponding housing in order to fix the position of the magnetic substance holder 100. As shown in FIG. 18, the support part 410 may include a coupling part 411 in which a coupling hole being coupled with the magnetic substance holder 100 is formed, and two connecting parts 412 and 413 being extended across the through hole to the side surface of the housing and are connected to the coupling part. A groove into which a guide part 116 of a frame 110 is fitted can be formed in the coupling hole, and the frame 110 can be inserted into the coupling hole so that one surface of the second hook-coupling part 117 and the coupling part can be hook-coupled and fixed.

A magnetic substance holder 100 includes a frame 110 having a through hole being formed in a lengthwise direction therein and a first fastening part formed on an outer surface, a magnetic substance 130 disposed on an outer surface of the frame 110 and having a through hole formed therein, and a fixing part 120 being disposed on an outer surface of the frame 110 and having a through hole formed therein, and a second fastening part corresponding to the first fastening part is formed on an inner surface of a through hole of the fixing part 120. The magnetic substance holder 100 can increase space utilization by being disposed on a penetrating through passage being formed by the coupling of the coupling parts of the first housing 400 and the second housing 500.

The first fastening part may include a plurality of first hook-coupling parts having different separation distances from one end of the frame 110.

The position of the first fastening part may correspond to the length of the magnetic substance 130 in a lengthwise direction. The first fastening part includes a plurality of first fastening parts, and includes at least one planar surface along a lengthwise direction of an outer surface of the frame 110, and at least one first fastening part may be disposed on a planar surface. The outer surface of the frame 110 has a polygonal shape, and at least one first fastening part may be disposed on one surface of the surfaces forming the polygonal shape.

A plurality of holes may be formed in a circumferential direction on an outer surface of the frame 110, and a gasket 140 is disposed on an outer surface of the frame 110 and has a through hole being formed therein. The gasket 140 may be disposed between the fixing part 120 and the magnetic substance 130, and a cross-sectional area of the through hole of the magnetic substance 130 and a cross-sectional area of the through hole of the fixing part 120 may correspond to a cross-sectional area of the frame 110.

One end of the frame 110 may include a third fastening part being coupled with a housing 400 to which the magnetic substance holder 100 is fixed, and the third fastening part may include at least one guide part 116 being protruded circumferentially from an outer surface of the frame, at least one second hook-coupling part 117 being spaced apart from the guide part and formed on an outer surface of the frame 110, and an engagement threshold part 118 being protruded circumferentially along the perimeter of an outer surface of the frame 110.

After the frame 110 is fixed to a coupling hole of the first housing 400, the magnetic substance 130 is fitted to an outer surface of the frame 110, and the fixing part 120 is fitted to an outer surface of the frame 110 to fasten the first fastening part of the frame 110 and the second fastening part of the fixing part 120. At this time, before the magnetic substance 130 is fitted to an outer surface of the frame 110 and the fixing part 120 is fitted to an outer surface of the frame 110, a gasket 140 may be fitted to position the gasket 140 between the magnetic substance 130 and the fixing part 120. At this time, one end of the magnetic substance 130 is in contact with the support part 410 of the first housing 400, and the other end of the magnetic substance 130 is in contact with the fixing part 120 or gasket 140 to fix the position.

The first fastening part includes a first screw thread, and the second fastening part includes a second screw thread corresponding to the first screw thread, so that the frame 110 and the fixing part 120 can be screw-coupled. As shown in FIG. 22, the frame 110 and the fixing part 120 can be coupled not only through hook-coupling but also through screw-coupling. Using hook-coupling allows for easy assembly, and using screw-coupling allows for application without limitation on the length of the magnetic substance.

Although the present invention has been described with specific details such as specific components and limited examples and drawings, these have been provided only to help a more general understanding of the present invention, and the present invention is not limited to the above examples, and those with common knowledge in the field to which the present invention pertains can make various modifications and variations from such a description.

Accordingly, the spirit of the present invention should not be construed as being limited to the embodiments described, and all of the equivalents or equivalents of the claims, as well as the following claims, belong to the scope of the present invention.

1.-10. (canceled)

11. A magnetic substance holder comprising:
a frame having a through hole formed inside and a first fastening part formed on an outer surface thereof;
a magnetic substance disposed on the outer surface of the frame and having a through hole formed therein; and
a fixing part disposed on the outer surface of the frame and having a through hole formed therein,
wherein a second fastening part corresponding to the first fastening part is formed on an inner surface of the through hole of the fixing part.

12. The magnetic substance holder according to claim 11, wherein the first fastening part comprises a plurality of first hook-coupling parts having different separation distances from one end of the frame.

13. The magnetic substance holder according to claim 11, wherein a position of the first fastening part corresponds to a length of the magnetic substance in a lengthwise direction.

14. The magnetic substance holder according to claim 11, wherein the first fastening part comprises a plurality of first fastening parts,
wherein the frame comprises at least one planar surface along a lengthwise direction among the outer surface of the frame, and
wherein at least one first fastening part is disposed on the planar surface.

15. The magnetic substance holder according to claim 11, wherein the first fastening part comprises a plurality of first fastening parts,
wherein the outer surface of the frame has a polygonal shape, and
wherein at least one first fastening part is disposed on one surface among surfaces forming the polygonal shape.

16. The magnetic substance holder according to claim 11, wherein the first fastening part comprises a first screw thread, and
wherein the second fastening part comprises a second screw thread corresponding to the first screw thread.

17. The magnetic substance holder according to claim 11, wherein a plurality of holes is formed in a circumferential direction on the outer surface of the frame.

18. The magnetic substance holder according to claim 11, comprising a gasket disposed on the outer surface of the frame and having a through hole formed therein,
wherein the gasket is disposed between the fixing part and the magnetic substance.

19. The magnetic substance holder according to claim 11, wherein a cross-sectional area of the through hole of the magnetic substance and a cross-sectional area of the through hole of the fixing part are corresponding to a cross-sectional area of the frame.

20. The magnetic substance holder according to claim 11, comprising:
a third fastening part coupled with a housing to which the magnetic substance holder is fixed at one end of the frame.

21. The magnetic substance holder according to claim 20, wherein the third fastening part comprises:
at least one guide part protruded in a circumferential direction from the outer surface of the frame;
at least one second hook-coupling part formed on the outer surface of the frame and spaced apart from the guide part; and
an engagement part protruded in a circumferential direction along a perimeter of the outer surface of the frame.

22. An electronic device comprising:
a first housing and a second housing having a coupling part protruded from surfaces facing each other and a through hole in the coupling part; and
at least one magnetic substance holder disposed on a through passage formed when the first housing and the second housing are coupled,
wherein a support part is formed to support the magnetic substance holder across the through hole of at least one of the first housing and the first housing,
wherein the magnetic substance holder comprises:
a frame having a through hole formed inside and a first fastening part formed on an outer surface thereof;
a magnetic substance disposed on the outer surface of the frame and having a through hole formed therein; and
a fixing part disposed on the outer surface of the frame and having a through hole formed therein, and
wherein a second fastening part corresponding to the first fastening part is formed on an inner surface of the through hole of the fixing part.

23. The electronic device according to claim 22, wherein the first fastening part comprises a plurality of first hook-coupling parts having different separation distances from one end of the frame.

24. The electronic device according to claim 22, wherein a position of the first fastening part corresponds to a length of the magnetic substance in a lengthwise direction.

25. The electronic device according to claim 22, wherein the first fastening part comprises a plurality of first fastening parts,
wherein the frame comprises at least one planar surface along a lengthwise direction among the outer surface of the frame, and
wherein at least one first fastening part is disposed on the planar surface.

26. The electronic device according to claim 22, wherein the first fastening part comprises a plurality of first fastening parts,
wherein the outer surface of the frame has a polygonal shape, and
wherein at least one first fastening part is disposed on one surface among surfaces forming the polygonal shape.

27. The electronic device according to claim 22, wherein the first fastening part comprises a first screw thread, and
wherein the second fastening part comprises a second screw thread corresponding to the first screw thread.

28. The electronic device according to claim 22, wherein a plurality of holes is formed in a circumferential direction on the outer surface of the frame.

29. The electronic device according to claim 22, wherein the magnetic substance holder comprises a gasket disposed on the outer surface of the frame and having a through hole formed therein, and
wherein the gasket is disposed between the fixing part and the magnetic substance.

30. The electronic device according to claim 22, wherein a cross-sectional area of the through hole of the magnetic substance and a cross-sectional area of the through hole of the fixing part are corresponding to a cross-sectional area of the frame.
